(19) United States
(12) Patent Application Publication
(10) Pub. No.: US 2014/0183937 A1
(43) Pub. Date: Jul. 3, 2014

(54) Method and Device Producing Energy by Violating of the Principle of Conservation of Energy and Absolute Ways to Prove the Reality of Such Energy Production

(71) Applicant: Vesselin C. Noninski, New York, NY (US)

(72) Inventor: Vesselin C. Noninski, New York, NY (US)

(21) Appl. No.: 13/730,870

(22) Filed: Dec. 29, 2012

(51) Int. Cl. H03K 3/012

(52) U.S. Cl. CPC H03K 3/012; Y10S 74/09; H02N 11/008
USPC 307/2; 74/DIG. 9

(57) ABSTRACT

A method and device for the production of more energy than the input energy and/or for the production of energy without spending energy, in genuine violation of the principle of conservation of energy (CoE), through saving from the input energy, by utilizing the natural asymmetries in electrical systems caused by combinations of active and reactive elements, supplemented by favorable asymmetries caused by distorting the applied signals as well as by applying signals containing both constant and alternating part.

### BACKGROUND OF THE INVENTION

The present invention relates generally to a method and a device which find application for the production of more energy than the input energy and/or for the production of energy without spending energy, in genuine violation of the principle of conservation of energy (CoE). The energy obtained according to this invention, alternatively called excess energy or “energy out of nothing”, does not come about at the expense of a pre-existing (already existing) energy reservoir. Excess energy in this invention is produced as a result of saving from the input energy due to so far unrecognized favorable juxtaposition and interaction of real elements and factors, other than already available energy. Thus, the phrase “production of energy out of nothing” is only a way of expressing that there is no pre-existing energy reservoir but it does not mean that there are no other existing real components and factors, and their respective interactions, which are due to the method and device described herein, which in their totality allow for the production of energy, despite the absence of such energy prior to commencing the process. The method is based on utilizing natural asymmetries, so far unrecognized for the purposes of “production of energy out of nothing”, which exist in standard classical physics, and concretely for the purposes of this invention, in the classical theory of electricity (NOTE: classical theory of physics and classical theory of electricity in particular, exclude Einstein's theory of relativity and quantum mechanics). These asymmetries, inherent in the theory of electricity, exhibit themselves even under ideal conditions in RC or LC circuits (where R is resistance, C is capacitance and L is inductance) or combinations thereof, as well as, when using other well-known elements such as Zener diodes and so on. Thus, for example, it is a natural asymmetry, even in the ideal case, to have the capacitor in an RC-circuit obliterate any current offset even if the applied voltage does have voltage offset. Another natural asymmetry caused by a capacitor (or inductor) is causing a natural phase shift between the applied voltage and the current flowing through the circuit (in an RC-circuit current leads the voltage). On the other hand, voltage with offset, applied to a resistor, causes the current to retain offset and therefore, in the ideal case, the resistor does not exhibit a natural asymmetry in this particular respect (a natural asymmetry such as offset in voltage and no offset in current), neither does it induce a phase shift between the voltage and the current.

A further feature of the present invention is the possibility to increase the excess energy and even eliminate the input energy by designing favorable distortions of input signals such as voltages and currents, supplied to electronic circuits, containing elements capable of inducing natural asymmetries. Such elements are, for instance, capacitors or inductors or any combination thereof. These distortions of the applied signals, taking advantage of the non-ideal behavior of elements leading to asymmetries, add to the mentioned natural asymmetries which, as stated, some elements exhibit even under ideal conditions. Further inducing of asymmetries to, say, symmetric pure sinusoidal waves (pure sinusoidal waves are such having only the fundamental frequency), is achieved through adding distortions to these ideal sinusoidal waves. Distortions of a pure sinusoidal wave can be achieved, for instance, by adding to it a second and third harmonic.

A still further feature of the present invention is that the excess energy is obtained through the hybrid action of both constant and alternating signals applied to the device. Thus, Tesla has shown the advantages of alternating current. Edison, on the other hand, has been the advocate of direct (constant) current. However, neither of these two limiting cases can ensure, purely electrically, significant excess energy (that is, energy which is not at the expense of a pre-existing energy reservoir). To produce tangible excess energy, a combination of DC and AC signal, undistorted (pure) or favorably distorted (usually distorted applied voltage leading to distorted current), is needed, of appropriate form, such as skewed sinusoidal wave. An example of an appropriate skewed sinusoidal wave may be a wave with one of its half-periods enclosing a smaller surface area than the other half-period. Also, the applied voltage having voltage offset should result in no current offset, which is an asymmetry inherent in the classical theory of electricity, introduced by certain reactive elements.

Several methods and devices as well as possibilities have been proposed associated with violation of CoE but their functioning differs from the method and device described in the present text:
Dirac, P. A. M., Does Conservation of Energy Hold in Atomic Processes?, Nature, 137, 298-299, (1936), discusses disobeying of CoE as an exotic outcome of what is perceived by some as new physics.
Noninski, V. C. and Noninski, C. I., Method and Device for Determining the Obtained Energy During Electrolysis Processes, Bulgarian Patent BG 50838 A, 20 July, 1989, disclose method and device to determine the obtained energy in an undivided cell during electrolysis.
Noninski, V. C., The Undivided Cell—A Natural Producer of Excess Energy Due to Combining Electrolysis and Electrochemical Recombination, Acta Scientiae, 2, 45-49, (2010), discloses a method for the production of excess energy due to saving from the input energy in an undivided electrochemical cell.
Noninski, V. C., The Principle of Conservation of Energy Violated, Acta Scientiae, 1, 121-122, (2008), discusses violation of CoE in a mechanical device.

Violation of CoE in various ways is discussed in a number of other studies by V. C. Noninski.

So far no electrical devices have been proposed to produce energy without spending of energy, as the standard literature indicates:
Panofsky, W. K. H. and Phillips, M. (1962) Classical Electricity and Magnetism, 2^{nd} ed., Addison-Wesley, Reading, Mass.
Jackson, J. D. (1975), Classical Electrodynamics, 2^{nd} ed., John Wiley & Sons, New York
Purcell, E. M. (1985) Electricity and Magnetism, McGraw-Hill Book Co., New York
Fowler, R. J. (1995) Electricity. Principles and Applications, p. 202, McGraw-Hill

Accordingly, what is desired, and has not heretofore been developed, is a method and device wherein not only would the production of excess energy be more convenient and technological but a suitable construction and method can ensure avoiding the spending of the entire input energy altogether.

Furthermore, what is desired, and has not heretofore been developed, is a method and device for producing energy without spending energy that includes electronic circuits capable of inducing natural asymmetries, as described above, which are the subject of application of undistorted (pure) or distorted periodic signals, consisting of both constant and alternating part.

### BRIEF SUMMARY OF THE INVENTION

It is an object of the present invention to provide an electrical device for producing excess energy wherein produced energy is more than the energy spent.

It is an object of the present invention to provide an electrical device for producing excess energy including a possibility to produce energy without spending energy.

It is an object of the present invention to provide a means of controlling and increasing of the produced excess energy either through applying undistorted (pure) waves or through distortion of the input waves.

It is an object of the present invention to provide a means of controlling and increasing of the produced excess energy through utilizing the natural asymmetries in an electric circuit.

It is an object of the present invention to provide a means of controlling and increasing of the produced excess energy through applying a hybrid signal, consisting of a constant and alternating part, to an electric circuit.

It is an object of the present invention to provide a method for inducing a phase-shift between voltage and current used to calculate power in an electrical system, in addition to the natural phase shift between applied voltage and current, which exists due to the concrete parameters of the circuit elements, by applying voltage offset which results in no current offset, the latter comprising an inherent natural asymmetry in electrical systems.

### BRIEF DESCRIPTION OF THE DRAWINGS

FIG. 1 is a schematic diagram of the experiment. R is a metal-oxide 9.954Ω resistor (measured by a 4-wire method, using Keithley Model 2000 multimeter) while C is a 1×10⁻¹⁰ F capacitor. The HP 8116A pulse generator applies a 798 kHz distorted sinusoidal wave of 8V amplitude and −8V offset. Measurement of voltage (CH4) and current (CH1) is done with a Tektronix DPO2014 oscilloscope using Tektronix P2221 1X_{1MΩ,110pF} passive voltage probe (experiments with 10X_{10MΩ,17.0pF} gave similar results) and a Tektronix TCP0030 Hall-effect current probe. The data is stored on a flash drive and processed using a spreadsheet.

FIG. 2 is a presentation of the current and voltage curves, from FIG. 1 for one period T of 1.252 μs. Each one of the 1253 points comprising the V and I curves is an average of 512 separate trigger events. Included are 3% error bars for V and 1% for I (errors are as given by the manufacturer of the oscilloscope and probes).

FIG. 3 is a presentation of the input and output energy obtained by integrating over time the momentary I and V products from FIG. 2. 3% propagated error bars are also shown.

FIG. 4 is a plot of current (cos t), (trace 2), and original-no-offset reference voltage (sin t), (trace 1), offset voltage (−0.5+sin t), (trace 3), and phase-shifted voltage (trace 4), juxtaposed.

FIG. 5 is a plot of current (cos t), (trace 2), and original-no-offset reference voltage (sin t), (trace 1), offset voltage (−0.5+sin t), (trace 3), and phase-shifted voltage (trace 4), juxtaposed.

FIG. 6 is a Plot of voltage with offset (trace 1), current (trace 2) and, as a reference, voltage without offset (trace 3).

FIG. 7 Schematic diagram of the studied circuit. Circuit is powered using a 30 MHz Agilent 33521A Function/Arbitrary Waveform Generator, current was measured by a Tektronix TCP0030 Hall effect current probe attached to a Tekronix DPO 2014 oscilloscope. R is 9.989Ω and C is 100 pF.

### DETAILED DESCRIPTION OF THE INVENTION

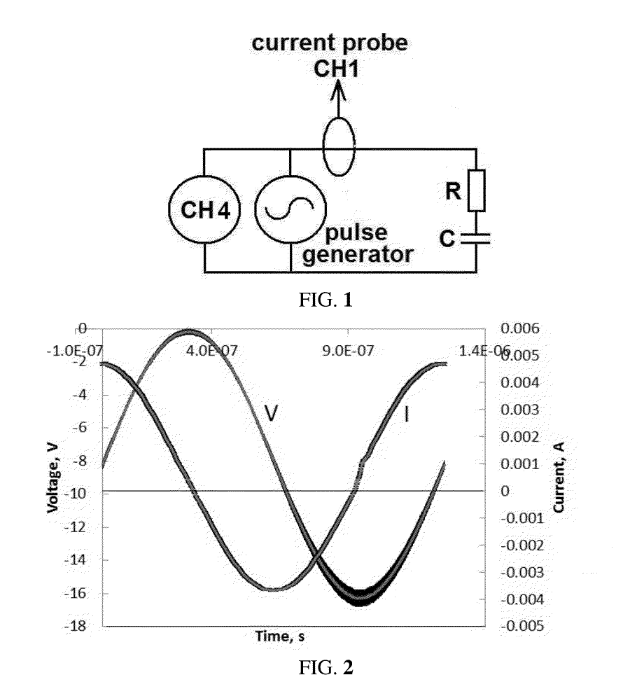

FIG. 1 shows a typical schematic diagram of the device whereby a pulse generator applies alternating voltage to an RC circuit and the ratio

$$\frac{{P}_{out}}{{P}_{in}}$$

between the average output power, Pₒᵤₜ, and the average input power, Pᵢₙ, within one period (or within multiple periods) is determined, using a digital storage oscilloscope. The main focus of this invention, for reasons obvious from the text to follow, is on Pᵢₙ. To ensure a better reproducibility each run is begun after first powering off all apparatus (after an over 20 min warming period) and going through the TCP0030 probe degaussing procedure each time after turning on all apparatus.

The average input and output powers are calculated from the obtained instantaneous values of current Iᵢ and voltage Vᵢ as

$$\begin{matrix}{P}_{in} = \frac{1}{n} {\sum }_{i = 1}^{n} {I}_{i} {V}_{i} \\ and & ( 1 ) \\ {P}_{out} = \frac{1}{n} {\sum }_{i = 1}^{n} {I}_{i}^{2} R & ( 2 )\end{matrix}$$

where n is the number of points into which the I−V curves are digitized within one period T (in this study n=1253). Alternatively, integration is carried out of the instantaneous input V(t)I(t) and output I(t)²R powers within one period T (or within multiple periods) to obtain the input and output energy as a function of time within that period(s)

Eᵢₙ=∫₀^{T}I(t)V(t)dt (3)

and

Eₒᵤₜ=∫₀^{T}I(t)²Rdt. (4)

This is accomplished numerically by applying Simpson's rule for data in rows 3 through 1255, as the following example for the input energy shows:

$${E}_{in} = 0 + ( {t}_{3} - {t}_{2} ) \frac{{I}_{3} {V}_{3} + {I}_{2} {V}_{2}}{2} + ( {t}_{4} - {t}_{3} ) \frac{{I}_{4} {V}_{4} + {I}_{3} {V}_{3}}{2} + … + ( {t}_{1255} - {t}_{1254} ) \frac{{I}_{1255} {V}_{1255} + {I}_{1254} {V}_{1254}}{2} \qquad ( 5 )$$

Output energy is integrated numerically in a similar way.

FIG. 2 shows the current and voltage curves for one period, obtained by using the device in FIG. 1 under the conditions indicated. FIG. 2 shows one especially interesting case of the voltage-current traces within one period. The traces in FIG. 2 are obtained at −8V offset, the voltage being a sinusoidal wave, distorted by adding second and third harmonics, respectively, through R407 and R409 trimmers of the HP 8116A pulse/function generator. Because of the asymmetry of the wave, it was observed that trimmer R407 affects the FFT peak, calculated by the DPO2014, at 0.00 Hz (which normally would be the peak of the offset), while R409 affects the peak at 1 MHz. In this case the respective peaks are 18.28 dB and 8.696 dB.

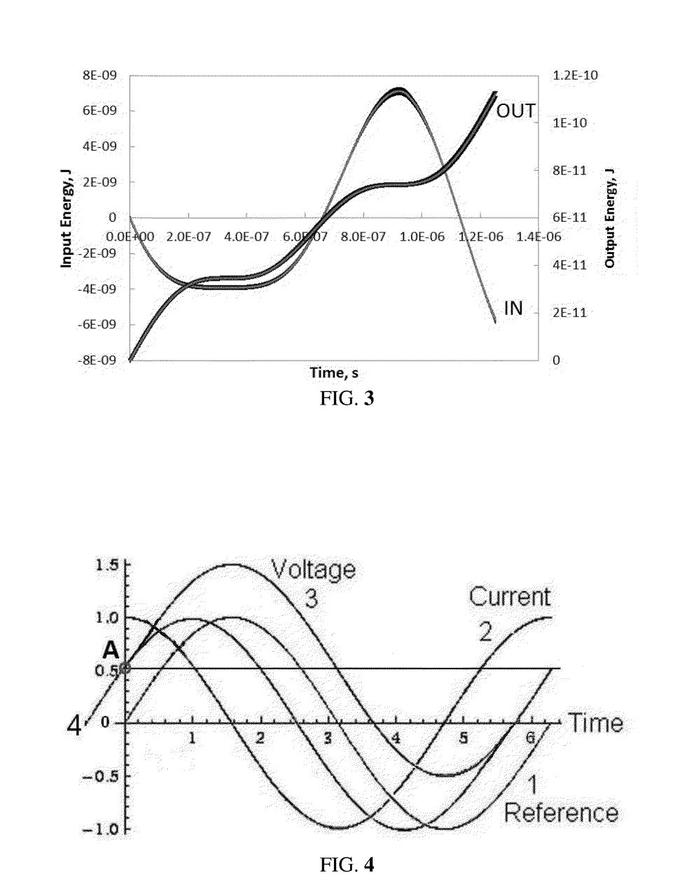

Finally, FIG. 3 shows the input and output energy traces within one period, obtained by integrating over time the instantaneous V(t)I(t) products from FIG. 2. As is seen from FIG. 3, while the output energy within one full period of 1.252 μs is inevitably positive, the corresponding associated input energy is negative. The conclusion is that energy has been produced without spending any energy, all the energy supplied by the pulse generator being returned back to the pulse generator for that period. This is in clear violation of conservation of energy and opens an entirely new, so far unsuspected, opportunity for the production of energy, based on hitherto unknown possibilities to violate CoE. This is inherent in classical physics—more specifically in the classical theory of electricity (NOTE: Classical physics, respectively, classical theory of electricity, do not include Einstein's theory of relativity and/or quantum mechanics.) The average input power, calculated according to eq. (1) from 10 separate determinations, each of which is exemplified by FIG. 2, is Pᵢₙ=−0.0046±0.0002 W. Therefore, the experimental input power is negative within ±3σ. On the other hand, the output power, conservatively, is nothing other than the dissipative always positive Joule heat due to passing of current through the 9.954Ω resistance of the RC circuit in FIG. 1 (cf. eq. (2)). Most importantly, it is always positive even if one imagines that the effective value of that dissipative resistance R would change due to parasitic effects at 798 kHz. To avoid distraction from the main issue—the observation of negative input power—by unsubstantiated speculations as to the actual value of R, which may be imagined to differ from the measured 9.954Ω when the circuit in FIG. 1 is powered, data for the output power (energy), dependent on R, as seen from eq. (2), are not presented. Note, by the way, that the speculations that the value of R under power may differ, because of parasitic effects, from its measured value in absence of current are overthrown at once by measuring the voltage drop across that R using another P2221 10X probe, simultaneously with measuring the already discussed input V and I, when power is applied to the circuit in FIG. 1. It is seen that the thus measured voltage drop across R practically coincides with the curve of the I, measured by the TCP0030 current probe. Thus, if the value R=9.954Ω, measured via 4-wire method using Keithley Model 2000 multimeter, is used to calculate Pₒᵤₜ, the

$$\frac{{P}_{out}}{{P}_{in}}$$

ratios change from being negative at negative voltage offsets, passing through unity at voltage offsets close to zero and having positive value less than unity for positive voltage offsets (keeping the same voltage amplitude with all studied voltage offsets). Therefore, violation of CoE is observed both at positive and negative offsets, the latter being of greater practical interest because, as seen, they provide the obtainment of energy without spending any energy, all the energy that the pulse generator applies being reflected back to the pulse generator.

Furthermore, as shown below, the effect of CoE violation, unnoticed so far, shows up purely theoretically when integrating the VI product over one period correctly, as well as when modeling V and I with concrete common parameters. Therefore, parasitic effects, which are present at high frequencies, will only affect the experimentally found magnitude of the CoE violation effect but cannot be its cause—the demonstrated CoE violation effect is real.

The output power, on the other hand, conservatively, is nothing else but the dissipative Joule heat due to passing of current through the 9.954Ω resistance of the RC circuit in FIG. 1. Most importantly, it is always positive even if one imagines that the effective value of R would change due to parasitic effects at 798 kHz. When ruminating over the reality of the reported effect notice that very slight changes in deformation of the sinusoidal wave (through adjusting R407 and R409 trimmers) lead to changing the value of the negative Pᵢₙ, even making it positive. This indicates that favorable distortion of the sinusoidal wave is a major factor for the obtainment of negative input power (for the production of energy without spending any energy). Also, with 9.954Ω with C=0 pF in FIG. 2 (that is, studying only the resistor R=9.954Ω) the

$$\frac{{P}_{out}}{{P}_{in}}$$

is practically 1 at all voltage offsets, unless future studies show that the slight (˜3%) discrepancies observed have statistical significance. The observed production of energy without spending any energy is based on the non-ideal response of reactive elements such as capacitors, which, upon designed favorable distortion of the wave, introduce additional asymmetries to the originally existing asymmetries, even when an ideal (symmetric, consisting of only the fundamental frequency) sinusoidal wave is applied to such circuits. The observed production of energy without spending any energy is not due to some new phenomenon, hitherto not present in the theory of electricity, as we know it. The discussed violation of CoE is inherent in the classical theory of electricity but it has not yet been recognized. It should also be mentioned that, although the energy produced is not obtained through depletion of an already existing energy reservoir, that energy is produced as a result of favorable interaction and juxtaposition of other real, although non-energy, attributes of the system, which in their totality lead to the production of energy.
Further Proof for the Reality of Observed COE Violation [PARA 36] As noted above, it is important to prove conclusively, that claimed excess energy, in violation of conservation of energy principle, is actually produced. In addition to the already described experiment, definitive proof for violation of conservation of energy in electrical systems can be provided in three different ways:
By a purely theoretical argument, based on physically consistent mathematics (trigonometric argument).
By using formulae, known from theory of electricity, for current, voltage and the power derived from them, and demonstrating hitherto unknown phenomena (numerical model).
Modified experimental demonstration by a method which would exclude interference of parasitic effects and would provide undeniable experimental results.

A Purely Theoretical Argument, Based on Physically Consistent Mathematics (Trigonometric Argument).

Standard texts [Panofsky and Phillips], [Jackson], [Purcell], [Fowler], treating as a rule symmetric periodic signals, propose that power applied to an electric circuit, such as an RC-group, be determined by multiplying the effective or rms values of the current and voltage in one period. Some use phasors for this purpose, and so on. However, it is well known that for more complex, non-symmetric signals without voltage offset F, the correct determination of average input power P̅ᵢ̅ₙ̅ in such electric circuits must be done by averaging the products V(t)I(t) of the instantaneous voltage and current values within a period, aided by modern digital technology.

So far it has not been known, however, that an intrinsic property of calculating the above V(t)I(t) product may not only put into question such studies, even when applying that more accurate approach, but also presents an inherent possibility for CoE violation. Furthermore, as will be shown below, the common method (and that is why it is being considered here at all) of multiplying the instantaneous current with the actually applied instantaneous voltage, gives an incorrect value of the instantaneous power when the instantaneous applied voltage has offset. As will be shown, in such a case, current must be multiplied by a voltage value which has a phase shift with respect to the original voltage (the original voltage is trace 1 in FIG. 6 discussed below). This means nothing else but an inherent violation of CoE because now the voltage which multiplies current will not have the natural phase shift

$$Θ = arctan ( \frac{1}{R 2 π f C} )$$

discussed below (the phase shift between trace 1 and trace 2 in FIG. 6—current leading voltage in an RC-circuit).

To understand the trigonometric argument, let us observe an undeniable property of the numerical treatment of periodic functions, hitherto unrecognized in the theory of electricity. As an illustration, consider the function cos t and divide its period [0, 2π] into 10 intervals. Then determine the value of cos t at each point blocking off the intervals and calculate the average cos t value at the 11 points, which obviously block off the 10 intervals. The expected value from such averaging is 0. However, the actually obtained average value is non-zero—it is approx. 0.09.

Notice, the work-around of considering that the 1^{st} and the 11^{th} points are weighted by a factor of ½ is unacceptable because those points do belong to the period [0, 2π] in full. For this same reason, dropping the last, 11^{th}, point in the averaging is also unacceptable. The problem explored in a study such as this, is not how to find a work-around, so that the result fits the expected outcome, but to determine the true outcome of the study.

Curiously, in the case of sin t, for the same period [0, 2π], divided into the same 10 intervals, the average of the 11 values is again not 0 but its value is different from the earlier obtained value of 0.09 for the cos t. It is on the order of 1.10⁻¹⁷. When trying to apply, for the sake of the argument, the above ½ weighting factor to the case of sin t, it is found that its effect also differs from that in the case of cos t and the average remains on the order of 1.10⁻¹⁷.

If we now consider sin t as the voltage V applied on an RC circuit and

$$I = C \frac{d V}{d t}$$

the current which V causes to flow through that circuit (where, C=const is the capacitance, which we consider, for simplicity, to be 1), then the average input power P̅ᵢ̅ₙ̅ for the [0, 2π] period is

$$\overline{{P}_{in}} = \frac{1}{11} {\sum }_{i = 0}^{i = 10} cos ( i \frac{2 π}{10} ) ( F + sin ( i \frac{2 π}{10} ) ) \qquad ( 6 )$$

Notably, it follows directly from the above properties of cos t and sin t that the power expressed by eq. (6) is dependent on the voltage offset F. Thus, while for F=0 its value is on the order of P̅ᵢ̅ₙ̅=−1.10⁻¹⁷, for an F=1 voltage offset the value of P̅ᵢ̅ₙ̅ becomes on the order of P̅ᵢ̅ₙ̅=0.09. These values are different from what is expected in the limiting case

$$\frac{1}{2 π} {\int }_{0}^{2 π} cos t ( F + sin t ) d x = 0.$$

As seen, the effect of offset F, which is a constant, is on the order of the observed discrepancy of cos t multiplied by F, the changing part sin t, understandably, having practically no effect.

Especially interesting is the result for F=−1 leading to a value, which is on the order of P̅ᵢ̅ₙ̅=−0.09. Negative average input power P̅ᵢ̅ₙ̅ for the period [0,2π] means that the inevitably produced positive average output power

$$\overline{{P}_{out}} = \frac{1}{11} {\sum }_{i = 0}^{i = 10} R {cos}^{2} ( i \frac{2 π}{10} ) = \frac{1}{11} {\sum }_{i = 0}^{i = 10} R {I}_{i}^{2} \qquad ( 7 )$$

has been obtained without any input, any energy produced by the generator per unit time being returned to it. This is an ultimate violation of CoE.

Numerical Model.

The above model findings, purely based on trigonometry, are illustrated numerically in FIG. 6 by a real-world example based on some common concrete values of the parameters which lead to Vᵢₙ and the corresponding Iᵢₙ, according to the well-known formulae

Vᵢₙ=(F+Vₘ sin(ωt) (8)

and

Iᵢₙ=A sin(ωtΘ) (9)

where Vₘ is the amplitude of the applied voltage, V; F is the offset voltage, V; ω=2πf is the angular velocity, rad s⁻¹;

$$f = \frac{1}{T}$$

is the frequency, Hz; T is the period, s; t is the time, s;

$$A = \frac{{V}_{m}}{\sqrt{{R}^{2} + {( \frac{1}{2 π f C} )}^{2}}} and Θ = arctan ( \frac{1}{R 2 π f C} ) .$$

The period [0,2π] in this case is divided into 1000 intervals (blocked off by 1001 points).
The value of

$$\frac{{P}_{out}}{{P}_{in}}$$

calculated as

$$\frac{\overline{{P}_{out}}}{\overline{{P}_{in}}} = \frac{\frac{1}{1001} {\sum }_{i = 1}^{i = 1001} {I}_{i}^{2} R}{\frac{1}{1001} {\sum }_{i = 1}^{i = 1001} {V}_{i} {I}_{i}} \qquad ( 10 )$$

for voltage without offset is 1.001. Voltage of 1V offset is

$$\frac{\overline{{P}_{out}}}{\overline{{P}_{in}}} = 0.716 ,$$

while voltage of −1V offset

$$\frac{\overline{{P}_{out}}}{\overline{{P}_{in}}} = 1.662 .$$

FIG. 6 and Table 1 show results for 5V, 0V and −5V offset.

TABLE 1

| Offset, V | P̅ᵢ̅ₙ̅, W | P̅ₒ̅ᵤ̅ₜ̅, W | P̅ₒ̅ᵤ̅ₜ̅ vs P̅ᵢ̅ₙ̅ |
|---|---|---|---|
| 5 | 3.77 × 10⁻⁶ | 1.26 × 10⁻⁶ | 0.33 |
| 0 | 1.26 × 10⁻⁶ | 1.26 × 10⁻⁶ | 1.00 |
| −5 | −1.25 × 10⁻⁶ | 1.26 × 10⁻⁶ | −1.01 |

As seen from FIG. 6, even in this common case of an RC circuit, the possibility to violate conservation of energy is inherent in the very theory of electricity, obtainment of more energy than the energy spent (position 3 in FIG. 6 apparently of a more practical significance than the violation of CoE when energy obtained is less than the energy input (position 2 in FIG. 6. Note that, unlike in the above trigonometric case, used for illustration, here in the concrete physical case, the absolute values of V and I differ by orders of magnitude and therefore the effect is not as pronounced as in the illustration. Conditions, however, can be found, as can be seen by changing the parameters for which FIG. 6 has been obtained, as has already been demonstrated also experimentally, to increase the P̅ᵢ̅ₙ̅ vs. P̅ₒ̅ᵤ̅ₜ̅ discrepancy and even to obtain a negative

$$\frac{\overline{{P}_{out}}}{\overline{{P}_{in}}}$$

ratio. The simplest way to modify the voltage signal with the aim to optimize the effect is through the introduction of harmonics, although other ways of modification as well as using various non-sinusoidal periodic signals is also a path for future research.

Modified Experimental Method.

The above findings can be also readily demonstrated experimentally with an experiment carefully designed to avoid the questions connected with parasitic effects (parasitic capacitances, inductance etc.), commonly arising when high frequencies are applied. Because the essence of the effect lies in the way averaging is done, presenting experimental data is redundant. We will only mention that Tektronix does averaging in the correct way pointed out above—when averaging, the number of data points is always one more than the number of equal intervals into which the period has been divided. Clearly, the last point must be included because it does belong to the period.

The improvement in question in the experimental method is the avoidance of a voltage probe, basing all the conclusions on reliable current measurements.

Thus, once current, I, has become available, voltage, V, comes out naturally due to the following intimate connection between current and voltage

$$V = \frac{1}{C} {\int }_{0}^{t} I d t , \qquad ( 11 )$$

where C is a constant (capacitance).

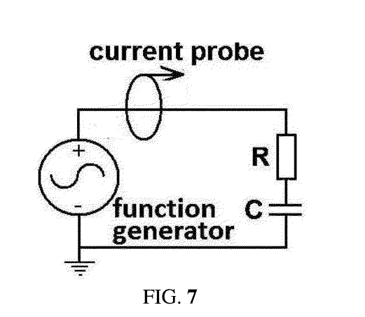

The connection between I and V in eq. (11) was used to design an experiment which avoids all concerns connected with the inevitable appearance of parasitic effect (capacitance, inductances) at high frequencies. For this reason, a Hall effect current probe is used to measure the current. It measures the electric fields generated around the conductors when current flows and converts the measured values into values of current without interrupting the circuit. Therefore, it is an absolute measurement which does not interfere with the processes in the system. The schematic diagram is shown in FIG. 7.

Therefore, once the current I is measured correctly using a state of the art Hall effect current probe, which measures current through electric fields external to the circuit, thus not interfering with the circuit, then the correct voltage will come out naturally through the above integral. It is obvious that due to the integration by eq. (11) the voltage thus obtained, however, will have lost its offset.

As explained, using the no-offset voltage from eq. (11) to calculate the power when the actual voltage has offset, will be in error. The effect of the offset must be taken into account. At this point, however, we will consider the effect of offset as part of the actually applied voltage, as was done in the above numerical examples. Later, this approach will also be shown to be incorrect.

Thus, at this point the average power within the period, considering the presence of offset, is calculated by correcting the integral value by the value of the offset F

$${V}_{true} = F + \frac{1}{C} {\int }_{0}^{t} I d t \qquad ( 12 )$$

and the true input power, P̅ᵢ̅ₙ̅, with actual input voltage containing F, is calculated as

$$\overline{{P}_{in}} = \frac{1}{2 π} {\int }_{0}^{2 π} {V}_{true} I d t \qquad ( 13 )$$

The general criticism that can be leveled at an approach, such as the above, in all of its variants, is that in it the individual discrete points are cherry-picked and when the number of intervals into which the period [0,2π] is divided is increased, tending towards the number of points blocking them off, the result approaches the expected 0, as the integral of a periodic function ƒ(t) and its first derivative f′(t); namely,

$${\int }_{0}^{2 π} f ( t ) {f}^{′} ( t ) = \frac{1}{2} {\int }_{0}^{2 π} d {f}^{2} ( t ) = \frac{1}{2} {f}^{2} ( t ) {\vert}_{0}^{2 π} = 0$$

will require.

Of course, this critique can be immediately countered by the fact that the calculation error increases with the increase of the number of intervals, which is a factor that may possibly smear the otherwise true non-zero effect.

A proof that computational (rounding) error, typical for digital machines, is the reason for the above-observed variation of the value of the sum with the number of intervals the period is divided into, is the fact that a similar sum, requiring less calculations and involving numbers of reasonable (away from the calculational limits of the digital machine) magnitude, such as

$$\frac{1}{n} {\sum }_{i = 0}^{i = n} cos ( \frac{2 π}{n} ) ( F + sin ( \frac{2 π}{n} ) ) \qquad ( 14 )$$

for a given F retains the constant value at any number of intervals n into which the period [0,2π] is divided.

Despite all the objections mentioned so far, it is evident that, even if averaging of actual instantaneous V(t)I(t) products is considered the correct way of determining power input (as is the common perception thus far), the above finding open ways to build electric circuits violating CoE. The necessary condition for that is to actually achieve the discrete signals discussed, instead of cherry-picking them from continuous signals. The newly designed experiment is an appropriate approach to achieve this, not only because it eliminates the usual concerns connected with parasitic effects, but also answers the objection that when calculating the V(t)I(t) in the model, based on common real parameters, the current we have calculated may not exactly correspond to the voltage used. The inference is that such correspondence is only true for a continuous signal, while we are analyzing only a finite number of discrete data. The voltage, however, derived from the experimental current, as is done in the newly designed experiment, is undoubtedly the exact corresponding voltage, not only in time but also in magnitude. It can be seen that the experimental P̅ᵢ̅ₙ̅ still depends on F.

When observing, within a period [0,2π], the plot of cos t juxtaposed on sin t it is noticed that the two traces cross each other at different points than when juxtaposing cos t and, say, −0.5+sin t. A clear difference in the run of the plot cos t sin t as a function of t compared to cos t (−0.5+sin t) as a function of t within a period [0,2π] is also seen. An impression is created that something resembling a phase shift may be playing a role for the fact that

$${\int }_{0}^{2 π} cost sin t$$

is zero, while

$${\int }_{0}^{2 π} cost ( - 0.5 + sin t )$$

is non-zero, even negative, leading to the conclusion that CoE is violated. This is a step towards understanding the correct way to determine the average input power P̅ᵢ̅ₙ̅, described below.

Conclusive Purely Theoretical Argument Based on Physically Consistent Mathematics.

It turns out that there is an unnoticed subtlety which definitively proves that any time AC voltage has a constant component (offset) F, there will always be a violation of CoE.

So far, the results and analysis presented were based on the common understanding that instantaneous power is to be determined by multiplying the instantaneous values of current and the values of the actually applied voltage, including when it contains offset.

However, when voltage has offset F, that DC part of the voltage does not participate in the input power—voltage offset F, being constant in time, causes no current when applied to an RC circuit, therefore the numerical value of F has no direct role in the formation of P̅ᵢ̅ₙ̅ in a sense that it does not participate in the product of current and voltage when correctly calculating P̅ᵢ̅ₙ̅. And yet, F does have a role. Let us observe now in more detail what that role is.

Current in an RC circuit is derived from voltage changing in time. In other words, it does not matter whether or not the voltage has a DC component (a voltage offset F). All that matters in deriving current from voltage within a period is the pattern of change which voltage displays within that period. Thus, ultimately, current derives from voltage without offset and, as already said, the presence of voltage offset does not matter when current is derived.

Therefore, when the following integral is written, in an attempt to calculate average power P̅ᵢ̅ₙ̅, applied to the RC circuit within a period,

$$\overline{{P}_{in}} = \frac{1}{2 π} {\int }_{0}^{2 π} cos ( t ) ( F + sin ( t ) ) d t , \qquad ( 15 )$$

nothing else is meant but the expression without the voltage offset F; that is, not only current but also voltage does not have an offset

$$\overline{{P}_{in}} = \frac{1}{2 π} {\int }_{0}^{2 π} cos ( t ) sin ( t ) d t . \qquad ( 16 )$$

Calculating power, as in eq. (16), however, is incorrect because if we calculate power that way, the current value at a given point of time will correspond to (and will be multiplied by) the value of the voltage without any consideration that voltage has offset, when it does. In this way voltage offset will have no bearing on power whatsoever (in addition to voltage offset having no bearing on the resulting current). The values of this non-offset voltage, although giving rise to the current, differ from the actual numerical values of the voltage which should be used in calculating the power. Eq. (16) multiplies current by the incorrect voltage value. Correct calculation of power requires multiplication of the instantaneous current by the correct instantaneous numerical voltage value, having to do with the actual voltage with offset, the effect of the latter actually being missing under the integral in eq. (16).

Thus, offset of the voltage does matter when voltage is used to calculate power but, surprisingly, not directly with its magnitude. In order to obtain correct value of the power, when voltage has offset F=const, the current at a given time t must be multiplied at that same time t by a voltage value which differs from the value of the voltage that has caused the current.

Another point which needs attention is that voltage which gives rise to current, is only phase-shifted with respect to the current, exactly as much as

$$I = C \frac{d V}{d t}$$

determines, and when real parameters are considered, exactly as much as eq. (8) and eq. (9) determine. Any deviation of this phase shift

$$Θ = arctan ( \frac{1}{R 2 π fC} ) ,$$

strictly set by these equations and the concrete parameters R, C and f, is an immediate sign of CoE violation.

The idea is that while voltage offset F plays no role in causing current, only the pattern of voltage change in time being of importance for that matter, offset F should play a role in the determination of power, despite the fact that the numerical value of F itself has no role in the numerical power calculation. The constant voltage, which is the offset part of the overall AC voltage, causes no current flow and therefore causes no power input. Therefore, multiplying the current at a given t by the voltage at that t, which includes offset F, will give an incorrect value of the input power P̅ᵢ̅ₙ̅. When considering the role of the voltage in the input power its offset F has to be eliminated and only the voltage values which belong to the changing (AC) part should be used in calculating the input power correctly.

Now, if the offset of the voltage shown in trace 3 of FIG. 4 is eliminated by bringing the voltage trace vertically downwards, back to its non-offset reference position (trace 1), then the initial point A of the offset voltage (trace 3) will not belong to the AC part of the actually applied voltage any more. However, it must belong—only the product at t=0 of the current at t=0 by the actual voltage applied at t=0 gives the correct power at t=0. Indeed, it should go without saying that the real voltage value where point A is positioned should be used in calculating the power and the only thing necessary is to remove offset.

The only trace which can possibly retain the pattern of change of the offset voltage (the AC part), losing its offset (its DC part) at that and having the point A belong to it (that is, being one of the points of the AC part of the actually applied voltage), is the non-offset voltage trace 4, phase-shifted with respect to voltage trace 1. Notice, trace 4 is not voltage which current is derived from. Trace 4 only provides the correct voltage values, which the corresponding values of current must be multiplied by, so that correct input power values can be obtained, in consideration of the fact that the applied voltage has offset.

Thus, for instance, if the voltage is 0.5+sin(t), depicted by trace 3 in FIG. 4, that voltage, which otherwise (without the voltage having offset), would be sin(t) (trace 1), now, when the voltage has offset, must be changed, in accordance with what was just said, to

$$sin ( t + \frac{π}{6} ) ,$$

shown as trace 4, in order for the power to be calculated correctly through integration. Therefore, if input power P̅ᵢ̅ₙ̅ is to be calculated correctly, the corrected mutual disposition of current and voltage, trace 4 and trace 2 shown in FIG. 4, should be used instead of trace 1 and trace 2 shown in FIG. 4. This will result in

$$\overline{{P}_{in}} = \frac{1}{2 π} {\int }_{0}^{2 π} cos ( t ) sin ( t + \frac{π}{6} ) d t = 0.25 \qquad ( 17 )$$

The phase-shifting of voltage is done only to have the correct momentary V(t)I(t) products and does not mean that a discrepancy in the timing of the current and voltage is introduced—under the integral the phase-shifting of the voltage only transports the correct voltage value, mindful of its offset, to coincide properly with the current. In other words, in the long run, offset translates as a phase shift of the non-offset voltage when calculating power correctly.

When the offset F is equal to the amplitude of the sinusoidal voltage, then the voltage used to calculate power is so phase-shifted with respect to the original voltage (trace 1) that its phase coincides with the phase of the current.

The offset can be greater than the amplitude of the applied sinusoidal voltage pattern (cf. trace 1, which exhibits the pattern). In such a case, the voltage values used to calculate power will be further phase-shifted with respect to the original voltage (trace 1), in addition to the

$$\frac{π}{2}$$

phase snuff corresponding to the offset equaling the amplitude of the sinusoidal current, F=Vₘ. Finally, the values of the original voltage trace (trace 1) can be used to calculate power correctly when the offset becomes F=4Vₘ. For F>4Vₘ the picture repeats itself, a point, corresponding to F=4.5Vₘ, being just as point A in FIG. 4, as an example.

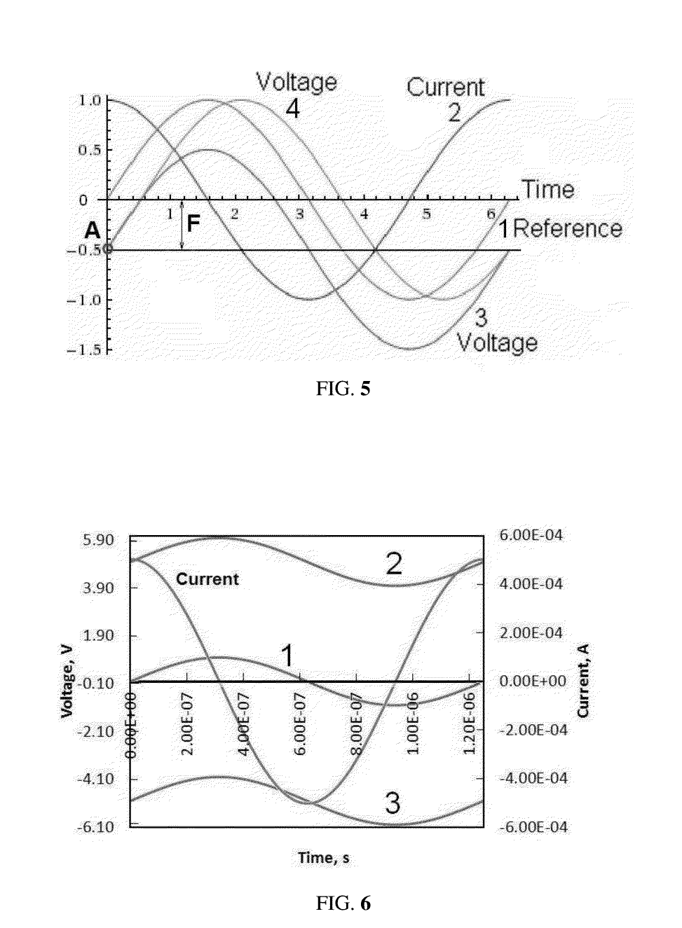

Especially interesting is the case when the offset is negative, say, F=−0.5 and the voltage has the form −0.5+sin t, as trace 3 in FIG. 5. Then,

$$\overline{{P}_{in}} = \frac{1}{2 π} {\int }_{0}^{2 π} cos ( t ) sin ( t - \frac{π}{6} ) d t = - 0.25 . \qquad ( 18 )$$

As explained above, when under the integral, the instantaneous current must be multiplied by the numerical value of a properly phase-shifted voltage. Otherwise the integral obliterates the offset of the voltage, causing the current to be multiplied by the wrong voltage value, unaffected by the fact that said voltage has offset.

As seen from eq. (18), instead of a positive value (when a dissipative element R is present) or a zero, which is the usually known result of integrating power in passive circuits, the value of the integral is negative. This means that the action of the generator in this illustration is to return energy to the generator while producing energy; namely, Joule heat P̅ᵢ̅ₙ̅=I²R, on the dissipative element R. In other words, to produce energy per unit time, the generator not only does not spend energy but has energy returned to it. This is an outright violation of conservation of energy due to inherent asymmetries in electrical systems.

To avoid confusion, it should be recalled also that standard literature [Panofsky and Phillips], [Jackson], [Purcell], [Fowler] requires that the power balance be carried out only for the power coming into and out of the electric circuit. The power needed to run the generator is not included in the power balance. Therefore, it is not a requirement for violating CoE to demonstrate a self-sustaining system, powered by the excess power produced at the output.

The general conclusion is that any time there is a DC voltage offset, together with AC voltage, there is a violation of conservation of energy—either by the obtainment of more or the obtainment of less energy than the energy put into the system. This conclusion is in harmony with other observations of CoE violation, whereby energy produced does not come from a previously existing energy reservoir but comes about due to saving from the input as a result of favorable juxtaposition of the elements of the system and its construction [Noninski]

Obeying of CoE in electrical systems when continuous signal are applied is only an exception. CoE in such cases is abided by only when when F=0 or, in general, when the elements of the circuit are only active (dissipative).

Of course, the same analysis and conclusions hold also to more complex forms of the applied voltage such as sinusoidal signals containing higher harmonics as well as periodic signals other than sinusoidal. The above analysis provides an opportunity to look for greater effects showing more expressed violation of CoE.

It should also be obvious that when the circuit consists of only active, dissipative, elements, such as resistors, not only will there be no natural phase shift between current and voltage at any F value but there will be no phase shift between the applied voltage with any F and the voltage value used for the power calculation according to the above considerations. When there is F≠0 in the voltage applied on a resistor, current will, symmetrically, also have an offset. Thus, in this case of active resistance, the offset in voltage causes offset in current and these offsets (in voltage and current) should be included in the calculation of power. Therefore, in this case, the correct power value is equal to the product of the actually applied instantaneous current and voltage. In the case of an active resistance, there is no natural asymmetry between current and voltage of the type described above and therefore there will be no violation of CoE due to phase-shifting of voltage, used to calculate power with respect to its actually applied value, as in the above case of passive resistance. Violation of CoE in the case of active resistance may be sought along the lines of the demonstrated discrepancy in the treatment of discrete, finite number of values within a period or by looking for other asymmetries not under consideration in this text.

Purely electric methods, even just purely theoretical, of verifying the reality of the above effects are quite sufficient, provided the described correct method of determining input power P̅ᵢ̅ₙ̅ is applied.

What is claimed is:

1. A method and device comprising: an electrical circuit capable of producing more energy than the input energy or less energy than the input energy and/or capable of producing energy without spending energy, all three possibilities being in genuine violation of the principle of conservation of energy (CoE), containing elements inherently inducing asymmetries such as phase shift(s) between current and voltage and/or obliterating current offset despite the offset in voltage, even when ideal signals; that is, signals containing only the fundamental frequency, are applied to them, said asymmetries being enhanced by distorting of the applied signals as well as by having the applied signals contain both constant and alternating part.

2. The method and device of claim 1 wherein the electrical circuit contains active and/or reactive elements (capacitors and inductors) and/or other elements inducing asymmetries in the applied parameters leading to the violation of energy conservation.

3. The method and device of claim 1 wherein conditions are created such as imparting a voltage signal containing both AC and DC component, which cause a so far unsuspected phase-shift, additional to the phase shift which exists naturally between current and voltage in electrical circuits, said additional phase-shift leading to inevitable violation of conservation of energy.
